(19) United States
(12) Patent Application Publication
(10) Pub. No.: US 2013/0056343 A1
(43) Pub. Date: Mar. 7, 2013

(54) PROJECTED CAPACITIVE TOUCH PANEL

(71) Applicant: Jane Hsu, Taoyuan County (TW)

(72) Inventor: Jane Hsu, Taoyuan County (TW)

(73) Assignee: LIYITEC INCORPORATED, Taoyuan County (TW)

(21) Appl. No.: 13/592,912

(22) Filed: Aug. 23, 2012

(30) Foreign Application Priority Data
Sep. 2, 2011 (TW) 100216437

(51) Int. Cl. H03K 17/975

(52) U.S. Cl. 200/600

(57) ABSTRACT

A projected capacitive touch panel has multiple first electrode strings and multiple second electrode strings parallelly and alternately formed on a substrate. The first and the second electrode strings respectively have multiple first sensing electrodes and multiple second sensing electrodes connected in series, and have a first end and a second end. The first sensing electrodes of each first electrode string progressively decrease in area from the first end to the second end while the second sensing electrodes of each second electrode string progressively decrease oppositely. Accordingly, the difference of the RC values between each first electrode string and an adjacent second electrode string increases, and the accuracy of touch detection on edges of the touch panel is enhanced to facilitate the manufacture of oversized projected capacitive touch panels.

### BACKGROUND OF THE INVENTION

1. Field of the Invention

The present invention relates to a projected capacitive touch panel and more particularly to a projected capacitive touch panel enhancing accuracy of touch detection near edge, reducing manufacturing process for insulation and facilitating the manufacture of oversized touch panel.

2. Description of the Related Art

With reference to FIG. 7, a conventional projected capacitive touch panel has multiple X-axis electrode strings 71 and multiple Y-axis electrode strings 72 formed on a substrate 70. The X-axis electrode strings 71 are parallelly aligned in the direction of X axis. Each X-axis electrode string 71 has a first leading wire 710 connected with one end of the X-axis electrode string 71 and connected to one of a set of connection pads mounted on one side of the substrate 70 along edges of the substrate 70. Each X-axis electrode string 71 has multiple X-axis electrodes 711 connected in series with a first connection wire 712 connected between each adjacent two of the X-axis electrodes 711. The Y-axis electrode strings 72 are parallelly aligned in the direction of Y axis. Each Y-axis electrode string 72 is perpendicularly crossed by the X-axis electrode strings 71 and has a second leading wire 720 connected to another one of the set of connection pads mounted on the side of the substrate 70 along edges of the substrate 70. Each Y-axis electrode string 72 has multiple Y-axis electrodes 721 connected in series with a second connection wire 722 connected between each adjacent two of the Y-axis electrodes 721. When the X-axis electrode strings 71 and the Y-axis electrode strings 72 are formed on an identical surface of the substrate 70, each first connection wire 712 between two corresponding X-axis electrodes 711 is also crossly connected one of the second connection wires 722 between two corresponding Y-axis electrodes 721. With reference to FIG. 8, to avoid a short circuit, a separation layer 713 is formed between one of the first connection wires 712 and a corresponding second connection wire 722 crossed by the first connection wire 712.

From the foregoing structure, the conventional projected capacitive touch panel has the X-axis electrodes 711 and the Y-axis electrodes 721 aligned in the form of a matrix. A capacitance is formed between each X-axis electrode 711 and adjacent one of the Y-axis electrodes 721. Once a finger touches the adjacent X-axis electrode 711 and the Y-axis electrode 721, the capacitance therebetween is changed and a signal is transmitted to a controller through the set of connection pads connected with corresponding first leading wire 710 and second leading wire 720 to analyze and identify where the finger touches.

Despite the multi-touch feature and extensive applications in high-end products, such as smart phones, the projected capacitive touch panels still have many problems unsolved as follows.

1. Unsatisfactory accuracy of touch detection on edges of the touch panel: As mentioned, the X-axis electrodes 711 and the Y-axis electrodes 721 of the conventional projected capacitive touch panel are aligned in the form of a matrix. Besides the capacitance formed between adjacent X-axis electrode 711 and Y-axis electrode 721, each of the X-axis electrodes 711, the Y-axis electrodes 721, the first connection wires 712 and the second connection wires 722 has its own impedance. Hence, the closer the X-axis electrode 711 or the Y-axis electrode 721 to a corresponding X-axis leading wire 710 or Y-axis leading wire 720, the smaller the impedance of the X-axis electrode 711 or the Y-axis electrode 721 is. On the contrary, the farther the X-axis electrode 711 or the Y-axis electrode 721 away from a corresponding X-axis leading wire 710 or Y-axis leading wire 720, the higher the impedance of the X-axis electrode 711 or the Y-axis electrode 721 is. The X-axis electrodes 711 and Y-axis electrodes 721 relatively remote to the first leading wires 710 and second leading wires 720 are located adjacent to corresponding edges of the touch panel. In view of the impedance accumulation, the accuracy of touch detection on edges of the touch panel is relatively unsatisfactory. Under the circumstance, it is less likely to manufacture oversized projected capacitive touch panels.

2. More complicated in production: When the X-axis electrode strings 71 and the Y-axis electrode strings 72 are formed on an identical surface of the substrate 70, an additional manufacturing process for separating the first connection wires 712 on each X-axis electrode string 71 from the corresponding second connection wires 722 of the second electrode strings 72, such as after forming an indium tin oxide (ITO) layer on the substrate 70 and etching to form the X-axis electrode strings 71, further forming the separation layer 713 on each first connection wire 712 and then forming the corresponding second connection wire 722 on the separation layer 713 so that a short circuit does not occur between the first connection wire 712 and the second connection wire 722. However, the manufacturing process adds the complexity of the manufacturing process for the conventional projected capacitive touch panel.

### SUMMARY OF THE INVENTION

An objective of the present invention is to provide a projected capacitive touch panel progressively adjusting the areas of the sensing electrodes in each electrode string to achieve large difference of the RC values of the adjacent electrode strings, thereby enhancing the accuracy of touch detection on edges of the touch panel and facilitating the manufacture of oversized projected capacitive touch panels

To achieve the foregoing objective, the projected capacitive touch panel has a substrate, multiple first electrode strings and multiple second electrode strings.

The substrate has a surface.

The first electrode strings are parallelly formed on the surface of the substrate. Each first electrode string has multiple first sensing electrodes connected in series with one another and has a first end and a second end. The first sensing electrodes progressive decrease in area from the first end to the second end.

The second electrode strings are parallelly formed on the surface of the substrate. Each second electrode string has multiple second sensing electrodes connected in series with one another and has a first end and a second end. The first electrode strings and the second electrode strings are alternately arranged on the substrate. The second sensing electrodes progressive decrease in area from the second end to the first end.

Given the first sensing electrodes of each first electrode string progressively decrease in area from the first end to the second end and the second sensing electrodes of each second electrode string progressively decrease in area from the second end to the first end, the impedance of each sensing electrode on an identical electrode string can be adjusted. Besides, as the first and second sensing electrodes of the first and second electrode strings progressively decrease in area along opposite directions, the sensing electrodes progressively increasing in area are adjacent to the sensing electrodes progressively decreasing in area. Hence, the difference values of the RC values of adjacent sensing electrodes are widened so as to enhance the accuracy of touch detection near edge and facilitate the manufacture of oversized touch panels. On the other hand, the first and second sensing electrodes on the first and second electrode strings are arranged in the form of a matrix, and the first and second electrode strings are parallelly and alternately aligned. In other words, the first and second electrode strings do not intersect at all. Accordingly, a manufacturing process for forming a separation layer can be eliminate to simplify the manufacturing processes of the projected capacitive touch panel.

To achieve the foregoing objective, alternatively, the projected capacitive touch panel has a substrate, multiple first electrode strings and multiple second electrode strings.

The substrate has a surface.

The first electrode strips are parallelly formed on the surface of the substrate. Each first electrode strip has a first end and a second end and progressive decreases in width from the first end to the second end.

The second electrode strings are parallelly formed on the surface of the substrate. Each second electrode string has multiple second sensing electrodes connected in series with one another and has a first end and a second end. The first electrode strings and the second electrode strings are alternately arranged on the substrate. The second sensing electrodes progressive decrease in area from the second end to the first end.

Given each first electrode strip progressively decrease in width from the first end to the second end and the second sensing electrodes of each second electrode string progressively decrease in area from the second end to the first end, the impedance of each second sensing electrode on an identical second electrode string can be adjusted. Besides, as the first electrode strips and the second electrode strings progressively decrease in width and area along opposite directions, the second sensing electrodes progressively decreasing in area are adjacent to the first electrode strings progressively decreasing in width. Hence, the difference values of the RC values of adjacent sensing electrodes are widened so as to enhance the accuracy of touch detection near edge and facilitate the manufacture of oversized touch panels.

Other objectives, advantages and novel features of the invention will become more apparent from the following detailed description when taken in conjunction with the accompanying drawings.

### BRIEF DESCRIPTION OF THE DRAWINGS

FIG. 1 is a plane view of a first embodiment of a projected capacitive touch panel in accordance with the present invention;

FIG. 2 is a partially enlarged plane view of the projected capacitive touch panel in FIG. 1;

FIG. 3 is another partially enlarged plane view of the projected capacitive touch panel in FIG. 1;

FIG. 4 is a plane view of a second embodiment of a projected capacitive touch panel in accordance with the present invention;

FIG. 5 is a partially enlarged plane view of the projected capacitive touch panel in FIG. 4;

FIG. 6 is another partially enlarged plane view of the projected capacitive touch panel in FIG. 4;

FIG. 7 is a plane view of a conventional projected capacitive touch panel; and

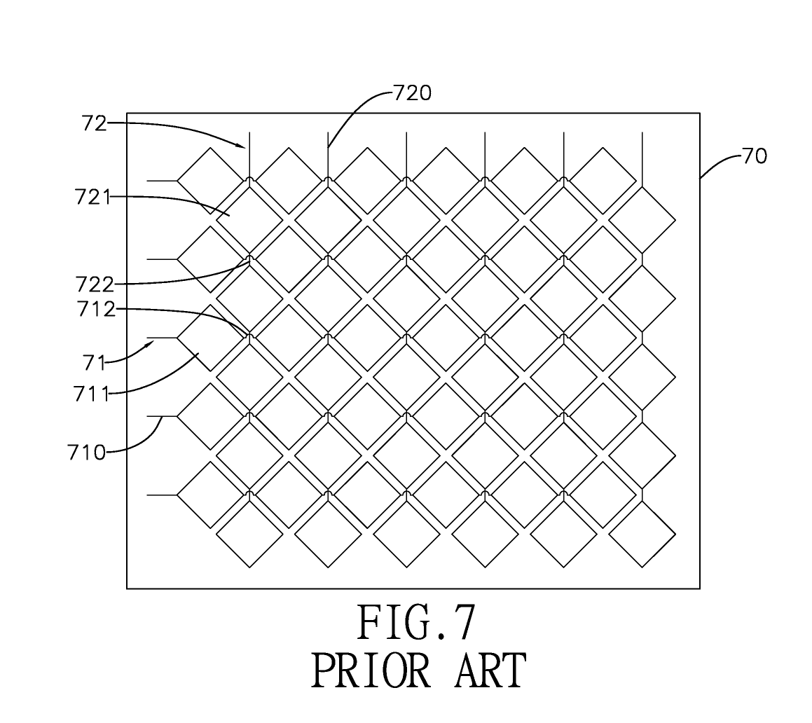

FIG. 8 is a side view in partial section of the conventional projected capacitive touch panel in FIG. 7.

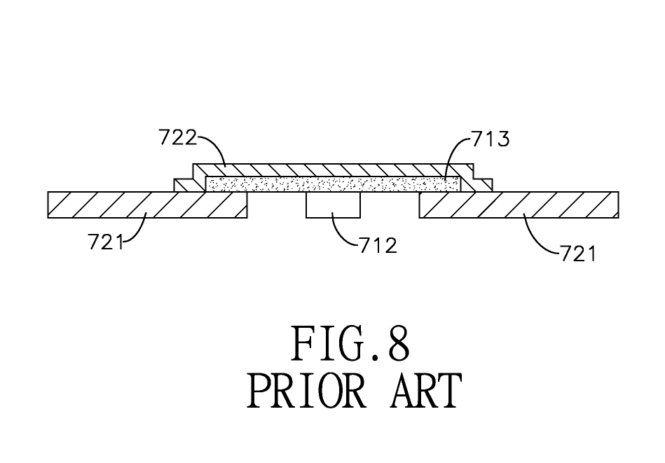

### DETAILED DESCRIPTION OF THE INVENTION

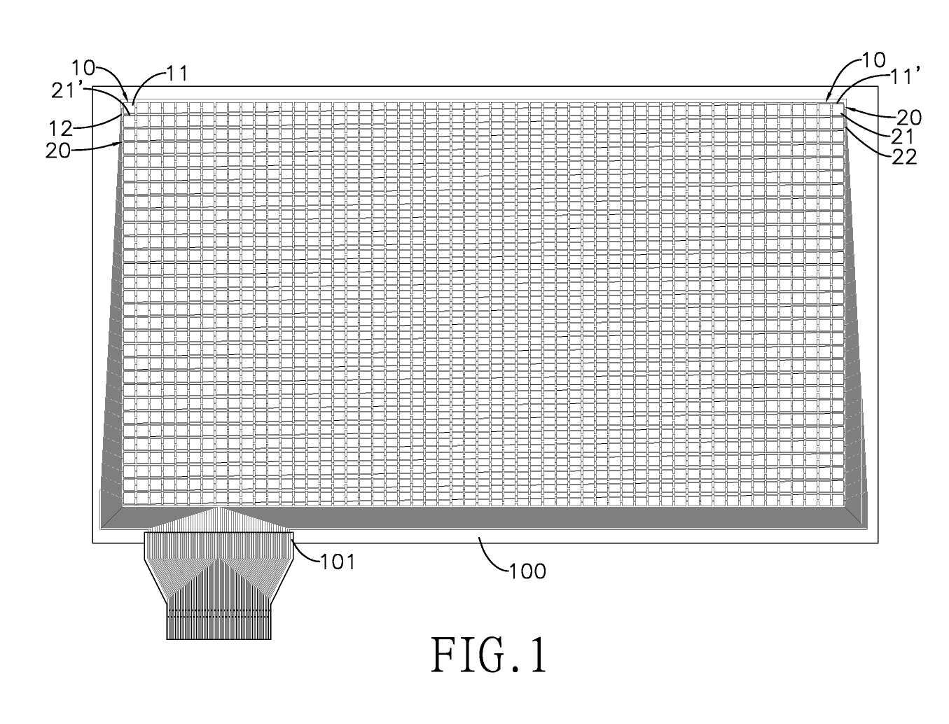

With reference to FIG. 1, a first embodiment of a projected capacitive touch panel in accordance with the present invention has a substrate 100, multiple first electrode strings 10, multiple second electrode strings 20 and a set of connection pads 101. The first electrode strings 10 and the second electrode strings 20 are formed on one surface of the substrate 1. The set of connection pads 101 is mounted on one side of the substrate 100 and is connected to an external controller.

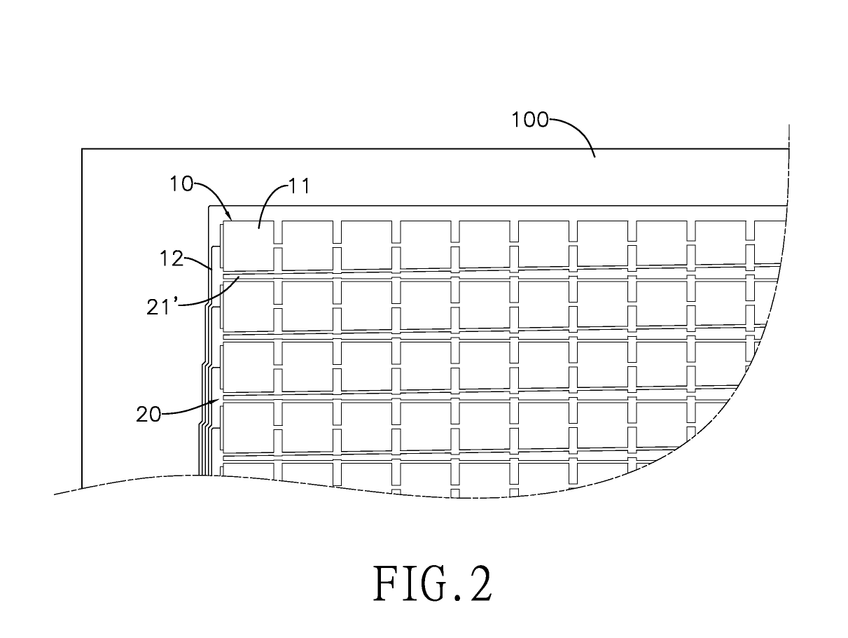

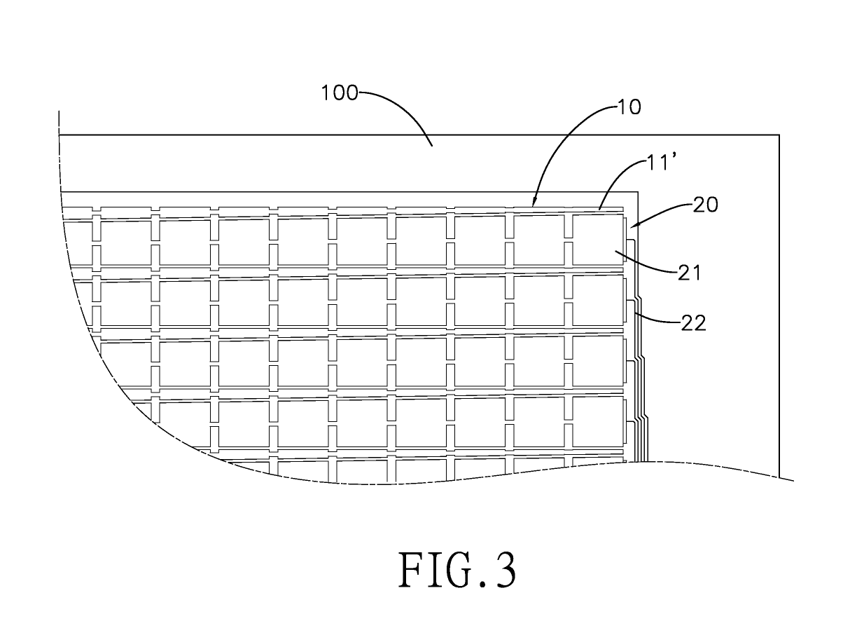

The first electrode strings 10 are parallelly formed on a surface of the substrate 100. In the present embodiment, the first electrode strings 10 are parallelly aligned in a horizontal direction and each first electrode string 10 has multiple first sensing electrodes 11, 11′ connected in series with one another. Each first electrode string 10 has a first end and a second end. In the present embodiment, the first end and second end respectively indicate the left end and the right end on the figures. The first sensing electrodes 11, 11′ progressive decrease in area from the first end to the second end. With reference to FIGS. 2 and 3, the first sensing electrode 11 on the first end of each first electrode string 10 has the largest area while the first sensing electrode 11 on the second end of each first electrode string 10 has the smallest area. In the present embodiment, the way of progressively decreasing the areas of the first sensing electrodes 11, 11′ is to keep the widths of the first sensing electrodes 11, 11′ intact and progressively decrease the heights thereof from the first end to the second end of the corresponding first electrode string 10. Hence, the first sensing electrodes 11, 11′ of the first electrode strings 10 directly align with one another in a vertical direction. Each first electrode string 10 has a first leading wire 12. One end of the first leading wire 12 is connected to the first end of the first electrode string 10 and the other end thereof is connected to one of the set of connection pads 101.

The second electrode strings 20 are parallelly formed on the surface of the substrate 100 in the horizontal direction. The first electrode strings 10 and the second electrode strings 20 are alternately arranged on the substrate 100 in the vertical direction. Each second electrode string 20 has multiple second sensing electrodes 21, 21′ connected in series with one another and has a first end and a second end. In the present embodiment, the first end and second end still respectively indicate the left end and the right end on the figures. The second sensing electrodes 21, 21′ progressive decrease in area from the second end to the first end. The second sensing electrode 21′ on the first end of each second electrode string 20 has the smallest area while the second sensing electrode 21 on the second end of each second electrode string 20 has the largest area. In the present embodiment, the way of progressively decreasing the areas of the second sensing electrodes 21, 21′ is to keep the widths of the second sensing electrodes 21, 21′ intact and progressively decrease the heights thereof from the second end to the first end of the corresponding second electrode string 20. Hence, the second sensing electrodes 21, 21′ of the second electrode strings 20 directly align with one another in the vertical direction. In other words, the first sensing electrodes 11′, 11 and the second sensing electrodes 21, 21′ are arranged in the form of a matrix. Each second electrode string 20 has a second leading wire 22. One end of the second leading wire 22 is connected to the second end of the second electrode string 10 and the other end thereof is connected to another one of the set of connection pads 101.

From the foregoing, the first sensing electrodes 11, 11′ of each first electrode string 10 progressively decrease in area from the first end to the second end and the second sensing electrodes 21, 21′ of each second electrode string 20 progressively decrease in area in an opposite direction from the second end to the first end. As the impedance of each of the first sensing electrodes 11, 11′ and the second sensing electrodes 21, 21′ is proportional to the area thereof, the impedance values of the first sensing electrodes 11, 11′ and the second sensing electrodes 21, 21′ can be adjusted by progressively decreasing the areas thereof. On the other hand, the areas of the first sensing electrodes 11, 11′ on each first electrode string 10 and those of the second sensing electrodes 21, 21′ progressively decrease along respective directions opposite to each other, and the first sensing electrodes 11, 11′ with progressively decreasing areas are adjacent to the second sensing electrodes 21, 21′ with progressively increasing areas. Substantially, for each first electrode string 10 and an adjacent second electrode string 20, the first sensing electrode 11 and the second sensing electrode 21 with the largest area are respectively adjacent to the second sensing electrode 21′ and the first sensing electrode 11′ with the smallest area. As a result, the difference of the RC values (Resistive-capacitive constant) of the first sensing electrodes 11, 11′ and the second sensing electrode 21, 21′ on both sides of the respective and adjacent first electrode string 10 and the second electrode string 20 appears to be the largest. Because of the largest difference in the RC values, a touch signal can be easily detected and a calibration for detection accuracy can be easily performed. Thus, the unsatisfactory accuracy of touch detection on edges of the touch panel can be resolved in favor of the manufacture of oversized projected capacitive touch panels.

Moreover, as the first sensing electrodes 11, 11′ of the first electrode strings 10 and the second sensing electrodes 21, 21′ of the second electrode strings 20 are arranged in the form of a matrix and are parallelly and alternately aligned, it is impossible for the first electrode strings 10 and the second electrode strings 20 to intersect. Since there is no intersections between the first electrode strings 10 and the second electrode strings 20, the process of forming a separation layer can be removed from the entire manufacturing processes, thereby simplifying the manufacturing processes.

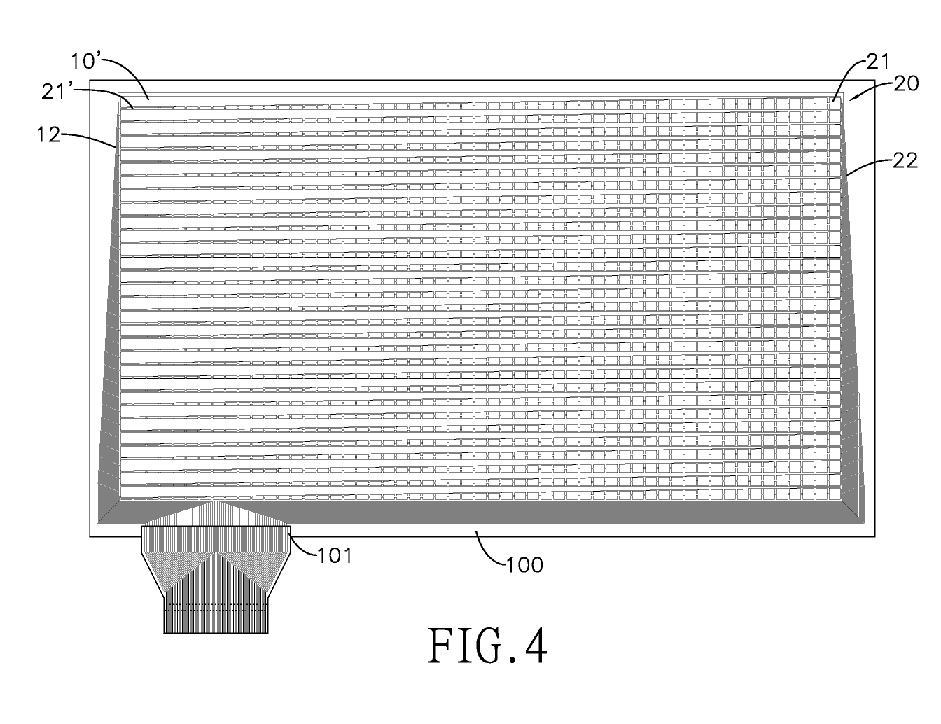

With reference to FIG. 4, a second embodiment of a projected capacitive touch panel in accordance with the present invention has a substrate 100, multiple first electrode strings 10′, multiple second electrode strings 20′ and a set of connection pads 101. The first electrode strings 10′ and the second electrode strings 20 are formed on one surface of the substrate 1. The set of connection pads 101 is mounted on one side of the substrate 100 and is connected to an external controller.

The second electrode strings 20 are structurally identical to those of the first embodiment, and are parallelly formed on a surface of the substrate 100. Each second electrode string 20 has multiple second sensing electrodes 21, 21′ connected in series with one another. Each second sensing electrode 21, 21′ progressively decreases in area from the second end to the first end. Each second electrode string 20 has a second leading wire 22. One end of the second leading wire 22 is connected to the second end of the second electrode string 10 and the other end thereof is connected to one of the set of connection pads 101.

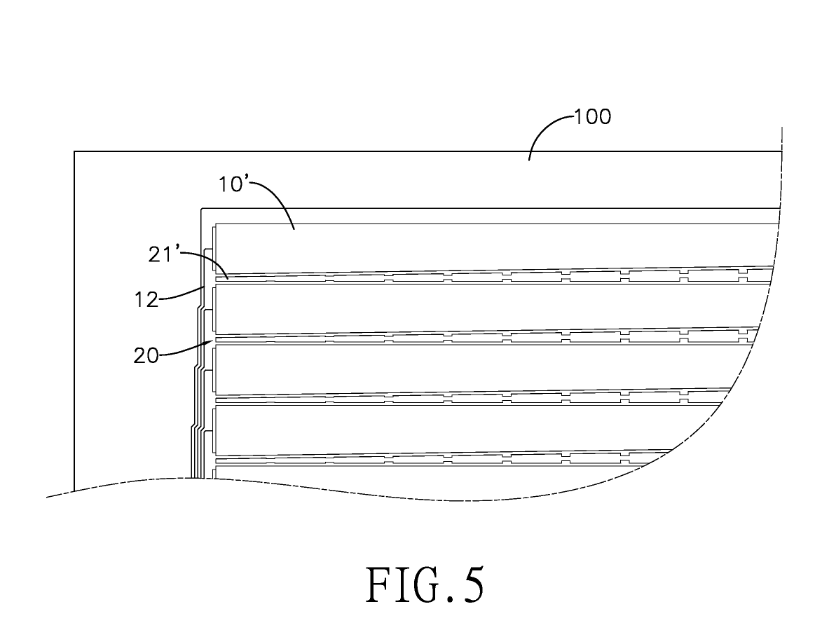

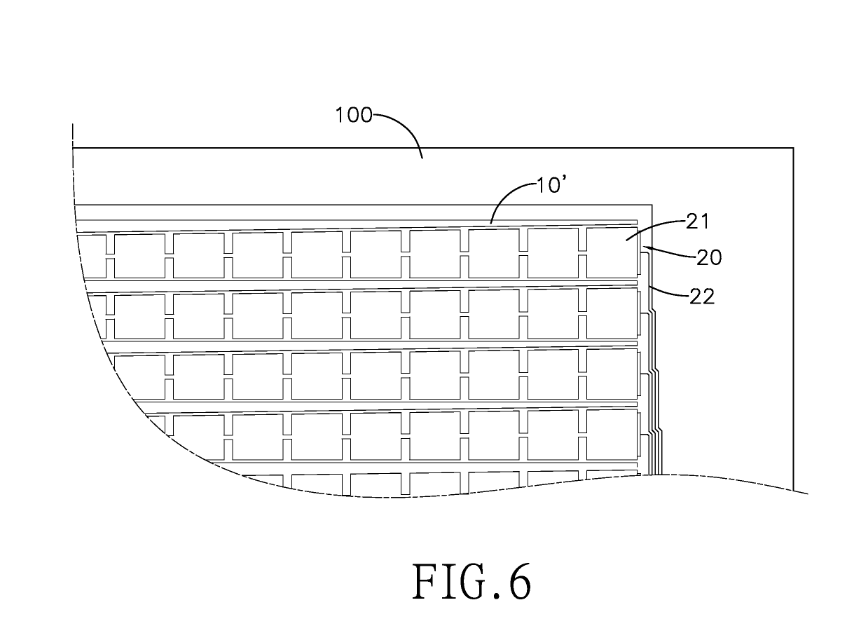

The first electrode strings 10′ are parallelly formed on the surface of the substrate 100. The first electrode strings 10′ and the second electrode strings 20 are parallelly and alternately arranged on the substrate 100. In the present embodiment, each first electrode string 10′ is an elongated and slender ITO layer whose width is measured along a vertical direction, and has a first end and a second end. The first end and second end still respectively denote the left end and the right end on the figures. Each first electrode string 10′ progressively decrease in width from the first end to the second end. With reference to FIG. 5, the closer to the first end, the larger the width of the first electrode string 10′ is. With reference to FIG. 6, the closer to the second end, the smaller the width of the first electrode string 10′ is. Each first electrode string 10′ has a first leading wire 12. One end of the first leading wire 12 is connected to the first end of the first electrode string 10′ and the other end thereof is connected to one of the set of connection pads 101.

In the present embodiment, the second sensing electrodes 21, 21′ of each second electrode string 20 progressively decrease in area from the second end to the first end, and each first electrode string 10′ progressively decreases in width in an opposite direction from the first end to the second end. Given such structure, the impedance of each second sensing electrode 21, 21′ on the second electrode string 20 is adjustable, and each first electrode string 10′ can be progressively decrease in width to correspond to the second sensing electrodes 21 progressively increasing in area on an adjacent second electrode string 20 so that the first electrode string 10′ progressively decreasing in width can be adjacent to the adjacent second electrode string 20 with the second sensing electrodes 21 progressively increasing in area. Accordingly, the difference of the RC values between each first electrode string 10′ and the second sensing electrodes 21, 21′ of an adjacent second electrode string 20 can be increased, a calibration for detection accuracy can be easily performed, the accuracy of touch detection on edges of the touch panel can be enhanced in favor of the manufacture of oversized projected capacitive touch panels.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A projected capacitive touch panel comprising:
a substrate having a surface;
multiple first electrode strings parallelly formed on the surface of the substrate, each first electrode string having multiple first sensing electrodes connected in series with one another and having a first end and a second end, wherein the first sensing electrodes progressive decrease in area from the first end to the second end; and
multiple second electrode strings parallelly formed on the surface of the substrate, each second electrode string having multiple second sensing electrodes connected in series with one another and having a first end and a second end, wherein the first electrode strings and the second electrode strings are alternately arranged on the substrate, and the second sensing electrodes progressive decrease in area from the second end to the first end.

2. The projected capacitive touch panel as claimed in claim 1, wherein
the substrate has a set of connection pads mounted on one side of the substrate;
each first electrode string has a first leading wire, wherein one end of the first leading wire is connected to the first end of the first electrode string and the other end thereof is connected to one of the set of connection pads; and
each second electrode string has a second leading wire, wherein one end of the second leading wire is connected to the second end of the second electrode string and the other end thereof is connected to another one of the set of connection pads.

3. The projected capacitive touch panel as claimed in claim 2, wherein
the first sensing electrodes remain intact in width and progressively decrease in height from the first end to the second end of a corresponding first electrode string; and
the second sensing electrodes remain intact in width and progressively decrease in height from the second end to the first end of a corresponding second electrode string.

4. A projected capacitive touch panel comprising:
a substrate having a surface;
multiple first electrode strips parallelly formed on the surface of the substrate, each first electrode strip having a first end and a second end and progressive decrease in width from the first end to the second end; and
multiple second electrode strings parallelly formed on the surface of the substrate, each second electrode string having multiple second sensing electrodes connected in series with one another and having a first end and a second end, wherein the first electrode strings and the second electrode strings are alternately arranged on the substrate, and the second sensing electrodes progressive decrease in area from the second end to the first end.

5. The projected capacitive touch panel as claimed in claim 4, wherein
the substrate has a set of connection pads mounted on one side of the substrate;
each first electrode strip has a first leading wire, wherein one end of the first leading wire is connected to the first end of the first electrode strip and the other end thereof is connected to one of the set of connection pads; and
each second electrode string has a second leading wire, wherein one end of the second leading wire is connected to the second end of the second electrode string and the other end thereof is connected to another one of the set of connection pads.

6. The projected capacitive touch panel as claimed in claim 5, wherein the second sensing electrodes remain intact in width and progressively decrease in height from the second end to the first end of a corresponding second electrode string.
